(19) United States
(12) Patent Application Publication
(10) Pub. No.: US 2016/0005791 A1
(43) Pub. Date: Jan. 7, 2016

(54) METHOD AND SYSTEM FOR PROVIDING A THIN PINNED LAYER IN A PERPENDICULAR MAGNETIC JUNCTION USABLE IN SPIN TRANSFER TORQUE MAGNETIC RANDOM ACCESS MEMORY APPLICATIONS

(71) Applicant: Samsung Electronics Co., Ltd., Gyeonggi-do (KR)

(72) Inventors: Xueti Tang, Fremont, CA (US); Dustin William Erickson, Morgan Hill, CA (US); Jangeun Lee, Cupertino, CA (US)

(21) Appl. No.: 14/731,164

(22) Filed: Jun. 4, 2015

Related U.S. Application Data
(60) Provisional application No. 62/020,937, filed on Jul. 3, 2014.

(51) Int. Cl. H01L 27/22; H01L 43/12; H01L 43/02; H01L 43/10

(52) U.S. Cl. CPC H01L 27/222; H01L 43/10; H01L 43/12; H01L 43/02

(57) ABSTRACT

A magnetic junction usable in a magnetic device and a method for providing the magnetic junction are described. The magnetic junction includes a free layer, a pinned layer and nonmagnetic spacer layer between the free and pinned layers. The free layer is switchable between a plurality of stable magnetic states when a write current is passed through the magnetic junction. The pinned layer has a perpendicular magnetic anisotropy energy greater than an out-of-plane demagnetization energy. The nonmagnetic spacer layer and the free layer are between the pinned layer and the substrate. The pinned layer has a pinned layer perpendicular magnetic anisotropy energy greater than a pinned layer out-of-plane demagnetization energy and a thickness of not more than thirty Angstroms.

### CROSS-REFERENCE TO RELATED APPLICATIONS

This application claims the benefit of provisional Patent Application Ser. No. 62/020,937, filed Jul. 3, 2014, entitled THIN PINNED LAYER IN PERPENDICULAR MTJ, assigned to the assignee of the present application, and incorporated herein by reference.

### BACKGROUND OF THE INVENTION

Magnetic memories, particularly magnetic random access memories (MRAMs), have drawn increasing interest due to their potential for high read/write speed, excellent endurance, non-volatility and low power consumption during operation. An MRAM can store information utilizing magnetic materials as an information recording medium. One type of MRAM is a spin transfer torque random access memory (STT-MRAM). STT-MRAM utilizes magnetic junctions written at least in part by a current driven through the magnetic junction. A spin polarized current driven through the magnetic junction exerts a spin torque on the magnetic moments in the magnetic junction. As a result, layer(s) having magnetic moments that are responsive to the spin torque may be switched to a desired state.

For example, FIG. 1 depicts a conventional dual magnetic tunneling junction (MTJ) 10 as it may be used in a conventional STT-MRAM. The conventional MTJ 10 typically resides on a substrate 12. A bottom contact 14 and top contact 24 may be used to drive current through the conventional dual MTJ 10 in a current-perpendicular-to-plane (CPP) direction, or along the z-axis as shown in FIG. 1. The conventional MTJ, uses conventional seed layer(s) (not shown), may include capping layers (not shown) and may include a conventional antiferromagnetic (AFM) layer (not shown). The conventional magnetic junction 10 includes a conventional bottom pinned layer 16, a conventional tunneling barrier layer 18, a conventional free layer 20, a conventional second tunneling barrier layer 22 and a conventional top synthetic antiferromagnetic (SAF) structure 30. The conventional SAF structure 30 includes a first pinned layer 32 (also known as a reference layer), a spacer layer 34 and a second pinned layer 36. Typically, the conventional pinned layer 16 is closest to the substrate 12 of the layers 16, 18 20, 22 and 30.

The conventional pinned layer 16, the conventional free layer 20 and the conventional pinned structure 30 are magnetic. The magnetizations 17, 33 and 37 of the conventional pinned layers 16, 32 and 36, respectively, are fixed, or pinned, in a particular direction. Although depicted as a simple (single) layer, the conventional pinned layer 16 may include multiple layers. For example, the conventional pinned layer 16 may be a SAF structure including magnetic layers antiferromagnetically coupled through thin conductive layers, such as Ru. In such a SAF, multiple magnetic layers interleaved with a thin layer of Ru may be used. In another embodiment, the coupling across the Ru layers can be ferromagnetic.

The conventional SAF structure 30 includes ferromagnetic pinned layers 32 and 36 separated by the nonmagnetic layer 34 that may be Ru. The magnetic moments 33 and 37 of the magnetic layers 32 and 36 are antiferromagnetically coupled. The conventional pinned layers 32 and 36 are typically quite thick. For example, the pinned layer 32 may include a CoFeB layer and multiple interleaved Co and Pt layers in order to achieve a perpendicular-to-plane orientation of the magnetic moment 33. In some cases the first pinned layer 32 is at least seventy-five Angstroms or more thick. Similarly, the second pinned layer 36 may be on the order of four hundred Angstroms thick or more.

The conventional free layer 20 has a changeable magnetization 21. Although depicted as a simple layer, the conventional free layer 20 may also include multiple layers. For example, the conventional free layer 20 may be a synthetic layer including magnetic layers antiferromagnetically or ferromagnetically coupled through thin conductive layers, such as Ru. Although shown as perpendicular-to-plane, the magnetization 21 of the conventional free layer 20 may be in plane. Thus, the pinned layer 16, free layer 20 and SAF structure 30 may have their magnetizations 17, 21, 33 and 37, respectively oriented perpendicular to the plane of the layers.

To switch the magnetization 21 of the conventional free layer 20, a current is driven perpendicular to plane (in the z-direction). When a sufficient current is driven from the top contact 22 to the bottom contact 14, the magnetization 21 of the conventional free layer 20 may switch to be parallel to the magnetization 17 of the conventional pinned layer 16. When a sufficient current is driven from the bottom contact 11 to the top contact 22, the magnetization 21 of the free layer may switch to be antiparallel to that of the pinned layer 16. The differences in magnetic configurations correspond to different magnetoresistances and thus different logical states (e.g. a logical “0” and a logical “1”) of the conventional MTJ 10.

Because of their potential for use in a variety of applications, research in magnetic memories is ongoing. Mechanisms for improving the performance of STT-RAM are desired. Accordingly, what is needed is a method and system that may improve the performance of the spin transfer torque based memories. The method and system described herein address such a need.

### BRIEF SUMMARY OF THE INVENTION

A magnetic junction usable in a magnetic device and a method for providing the magnetic junction are described. The magnetic junction includes a free layer, a pinned layer and nonmagnetic spacer layer between the free and pinned layers. The free layer is switchable between a plurality of stable magnetic states when a write current is passed through the magnetic junction. The pinned layer has a perpendicular magnetic anisotropy energy greater than an out-of-plane demagnetization energy. The nonmagnetic spacer layer and the free layer are between the pinned layer and the substrate. The pinned layer has a pinned layer perpendicular magnetic anisotropy energy greater than a pinned layer out-of-plane demagnetization energy and a thickness of not more than thirty Angstroms.

### BRIEF DESCRIPTION OF SEVERAL VIEWS OF THE DRAWINGS

FIG. 1 depicts a conventional dual magnetic junction.

FIG. 2 depicts an exemplary embodiment of a magnetic junction including a thin pinned layer and usable in a magnetic memory programmable using spin transfer torque.

FIG. 3 depicts another exemplary embodiment of a magnetic junction including a thin pinned layer and usable in a magnetic memory programmable using spin transfer torque.

FIG. 4 depicts another exemplary embodiment of a magnetic junction including a thin pinned layer and usable in a magnetic memory programmable using spin transfer torque.

FIG. 5 depicts another exemplary embodiment of a magnetic junction including a thin pinned layer and usable in a magnetic memory programmable using spin transfer torque.

FIG. 6 depicts another exemplary embodiment of a magnetic junction including a thin pinned layer and usable in a magnetic memory programmable using spin transfer torque.

FIG. 7 depicts an exemplary embodiment of a thin pinned layer for a magnetic junction usable in a magnetic memory programmable using spin transfer torque.

FIG. 8 depicts another exemplary embodiment of a thin pinned layer for a magnetic junction usable in a magnetic memory programmable using spin transfer torque.

FIG. 9 depicts another exemplary embodiment of a thin pinned layer for a magnetic junction usable in a magnetic memory programmable using spin transfer torque.

FIG. 10 is a flow chart depicting an exemplary embodiment of a method for providing a magnetic junction including a thin pinned layer and usable in a magnetic memory programmable using spin transfer torque.

FIG. 11 is a flow chart depicting another exemplary embodiment of a method for providing a thin pinned layer in a magnetic junction usable in a magnetic memory programmable using spin transfer torque.

FIGS. 12-15 depict another exemplary embodiment of a magnetic junction including a thin pinned layer and usable in a magnetic memory programmable using spin transfer torque during fabrication.

FIG. 16 depicts an exemplary embodiment of a memory utilizing magnetic junctions in the memory element(s) of the storage cell(s).

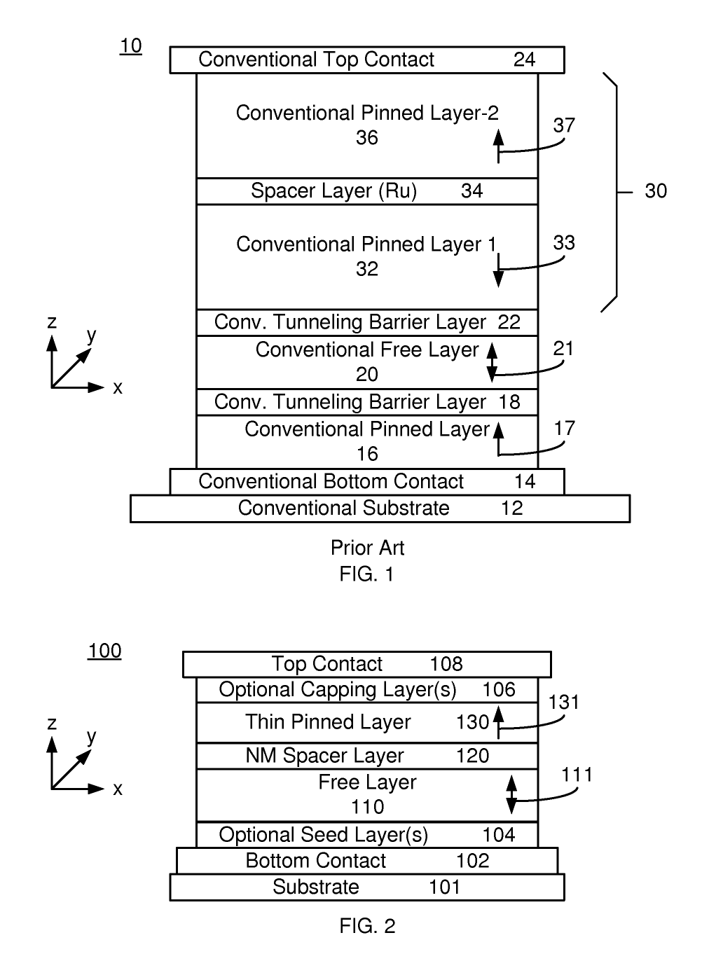

### DETAILED DESCRIPTION OF THE INVENTION

The exemplary embodiments relate to magnetic junctions usable in magnetic devices, such as magnetic memories, and the devices using such magnetic junctions. The magnetic memories may include spin transfer torque magnetic random access memories (STT-MRAMs) and may be used in electronic devices employing nonvolatile memory. Such electronic devices include but are not limited to cellular phones, smart phones, tables, laptops and other portable and non-portable computing devices. The following description is presented to enable one of ordinary skill in the art to make and use the invention and is provided in the context of a patent application and its requirements. Various modifications to the exemplary embodiments and the generic principles and features described herein will be readily apparent. The exemplary embodiments are mainly described in terms of particular methods and systems provided in particular implementations. However, the methods and systems will operate effectively in other implementations. Phrases such as “exemplary embodiment”, “one embodiment” and “another embodiment” may refer to the same or different embodiments as well as to multiple embodiments. The embodiments will be described with respect to systems and/or devices having certain components. However, the systems and/or devices may include more or less components than those shown, and variations in the arrangement and type of the components may be made without departing from the scope of the invention. The exemplary embodiments will also be described in the context of particular methods having certain steps. However, the method and system operate effectively for other methods having different and/or additional steps and steps in different orders that are not inconsistent with the exemplary embodiments. Thus, the present invention is not intended to be limited to the embodiments shown, but is to be accorded the widest scope consistent with the principles and features described herein.

A magnetic junction usable in a magnetic device and a method for providing the magnetic junction are described. The magnetic junction includes a free layer, a pinned layer and nonmagnetic spacer layer between the free and pinned layers. The free layer is switchable between a plurality of stable magnetic states when a write current is passed through the magnetic junction. The pinned layer has a perpendicular magnetic anisotropy energy greater than an out-of-plane demagnetization energy. The nonmagnetic spacer layer and the free layer are between the pinned layer and the substrate. The pinned layer has a pinned layer perpendicular magnetic anisotropy energy greater than a pinned layer out-of-plane demagnetization energy and a thickness of not more than thirty Angstroms.

The exemplary embodiments are described in the context of particular methods, magnetic junctions and magnetic memories having certain components. One of ordinary skill in the art will readily recognize that the present invention is consistent with the use of magnetic junctions and magnetic memories having other and/or additional components and/or other features not inconsistent with the present invention. The method and system are also described in the context of current understanding of the spin transfer phenomenon, of magnetic anisotropy, and other physical phenomenon. Consequently, one of ordinary skill in the art will readily recognize that theoretical explanations of the behavior of the method and system are made based upon this current understanding of spin transfer, magnetic anisotropy and other physical phenomena. However, the method and system described herein are not dependent upon a particular physical explanation. One of ordinary skill in the art will also readily recognize that the method and system are described in the context of a structure having a particular relationship to the substrate. However, one of ordinary skill in the art will readily recognize that the method and system are consistent with other structures. In addition, the method and system are described in the context of certain layers being synthetic and/or simple. However, one of ordinary skill in the art will readily recognize that the layers could have another structure. Furthermore, the method and system are described in the context of magnetic junctions and/or substructures having particular layers. However, one of ordinary skill in the art will readily recognize that magnetic junctions and/or substructures having additional and/or different layers not inconsistent with the method and system could also be used. Moreover, certain components are described as being magnetic, ferromagnetic, and ferrimagnetic. As used herein, the term magnetic could include ferromagnetic, ferrimagnetic or like structures. Thus, as used herein, the term “magnetic” or “ferromagnetic” includes, but is not limited to ferromagnets and ferrimagnets. As used herein, “in-plane” is substantially within or parallel to the plane of one or more of the layers of a magnetic junction. Conversely, “perpendicular” and “perpendicular-to-plane” corresponds to a direction that is substantially perpendicular to one or more of the layers of the magnetic junction.

FIG. 2 depicts an exemplary embodiment of a magnetic junction 100 having a thin pinned layer and which is usable in a magnetic memory programmable utilizing spin transfer. For clarity, FIG. 2 is not to scale. The magnetic junction 100 may be used in a magnetic device such as a STT-RAM and, therefore, in a variety of electronic devices. The magnetic junction 100 includes a free layer 110 having magnetic moment 111, a nonmagnetic spacer layer 120, and a thin pinned layer 130 having magnetic moment 131. Also shown is an underlying substrate 101 in which devices including but not limited to a transistor may be formed. Bottom contact 102, top contact 108, optional seed layer(s) 104 and optional capping layer(s) 106 are also shown. As can be seen in FIG. 2, the pinned layer 130 is closer to the top (furthest from a substrate 101) of the magnetic junction 100 than the free layer 110 is. The pinned layer 130 is also deposited after the free layer 110. The magnetic junction 100 is, therefore, a top pinned junction. In alternate embodiments, the magnetic junction 100 could be a dual magnetic junction. In such embodiments, at least an additional (bottom) nonmagnetic spacer layer (not shown in FIG. 2) and an additional (bottom) pinned layer (not shown in FIG. 2) would be present between the free layer 110 and the optional seed layer(s) 104/bottom contact 102. An optional pinning layer (not shown) may be used to fix the magnetization (not shown) of the pinned layer 130. In some embodiments, the optional pinning layer may be an AFM layer or multilayer that pins the magnetization (not shown) of the pinned layer 130 by an exchange-bias interaction. However, in other embodiments, the optional pinning layer may be omitted or another structure may be used. Other layers including but not limited to polarization enhancement layers (PELs) having a high spin polarization, magnetic or nonmagnetic insertion layers, and/or other layers may be included in the magnetic junction 100 but are not shown for simplicity.

The nonmagnetic spacer layer 120 may be an MgO tunneling barrier layer. The MgO layer may be crystalline and have a 200 orientation for enhanced tunneling magnetoresistance (TMR). In other embodiments, the nonmagnetic spacer layer may be a different tunneling barrier layer, may be a conductive layer or may have another structure.

The free layer 110 is magnetic and has a perpendicular magnetic anisotropy energy that exceeds the out-of-plane demagnetization energy. The free layer thus has a high perpendicular magnetic anisotropy (PMA). The magnetic moment 111 of the free layer 110 may thus be oriented perpendicular-to-plane as shown in FIG. 2. The magnetic junction is also configured such that the magnetic moment 111 of the free layer 110 may be switched using a current driven through the magnetic junction (e.g. using spin transfer). Although the free layer 110 is shown as a single layer, in some embodiments, the free layer 110 may be a multilayer. For example, the free layer 110 may be a SAF. The free layer 110 may also include multiple magnetic and/or nonmagnetic layers without being configured as a SAF structure.

The pinned layer 130 is magnetic. In some embodiments, the pinned layer 130 may be a multilayer. In some embodiments, the pinned layer 130 may be part of a pinning structure, such as a SAF. In such embodiments, the pinned layer 130 would be one of the ferromagnetic layers interleaved with nonmagnetic layer(s). In this and other embodiments, the pinned layer 130 may be a multilayer. Thus, the pinned layer 130 layer may also include sublayers including but not limited to multiple ferromagnetic layers. An optional pinning layer (not shown) may be used to fix the magnetization (not shown) of the pinned layer 130. Further, a polarization enhancement layer (PEL) having a high spin polarization may be provided between the pinned layer 130 and the magnetic spacer layer 120. Like the free layer 110, the perpendicular magnetic anisotropy energy of the pinned layer 130 exceeds its out-of-plane demagnetization energy. Consequently, the magnetic moment 131 of the pinned layer 130 may be perpendicular-to-plane. In such embodiments, a pinning layer is generally not used.

The pinned layer 130 is a thin pinned layer. Thus, the thickness of the pinned layer 130 (in the z-direction) is not more than thirty Angstroms in the completed magnetic junction 100. In some such embodiments, the thickness of the pinned layer 130 is not more than twenty-five Angstroms. Despite its small thickness, the pinned layer 130 may be a multilayer. For example, the pinned layer may include a CoFeB layer and at least one Co layer. In such embodiments, the CoFeB layer may be closer to the nonmagnetic spacer layer 120 than the Co layer(s). The thickness of the CoFeB layer may be at least five Angstroms and not more than twenty Angstroms in the completed magnetic junction. In some such embodiments, the CoFeB layer is not more than fifteen Angstroms in the completed magnetic junction. In some embodiments, the CoFeB layer is at least eight Angstroms and not more than twelve Angstroms thick in the completed magnetic junction 100. As discussed below, during fabrication, the thickness of the CoFeB layer may be greater than twenty Angstroms. The CoFeB layers may have the following stoichiometry: Co: 1-30 atomic percent, Fe: 40-99 atomic percent and B: 1-50 atomic percent. In some such embodiments, the CoFeB layers may have concentrations as follows: Co 10-20 atomic percent, Fe: 60-90 atomic percent and B 10-30 atomic percent. Thus, indicating that a layer includes CoFeB does not require a particular stoichiometry (i.e. does not require equal amounts of Co, Fe and B). The Co layer(s) may have a thickness of at least three Angstroms and not more than five Angstroms. In some embodiments, the pinned layer 130 also includes two Co layers separated by an insertion layer, such as Pt, Pd and/or Rh. In such embodiments, the Co layers are each at least three and not more than five Angstroms thick. The insertion layer may be at least two and not more than five Angstroms thick in such embodiments. However, the thickness of the pinned layer 130 including the CoFeB layer, Co layers and insertion layer may still be desired not to exceed thirty Angstroms.

The magnetic junction 100 may have improved performance. The free layer 110 and pinned layer 130 may have their magnetic moments oriented perpendicular-to-plane, which may be desirable for improved performance. In addition, the pinned layer 130 may be relatively thin. As a result, the pinned layer 130 has a small Mst (saturation magnetization multiplied by the thickness in the z-direction). The shift field at the free layer 110 due to the pinned layer 130 may be smaller. The response of the free layer 110 may be more symmetric. The nonmagnetic spacer layer 120 may also have the desired crystal structure (e.g. crystalline 100 MgO) for higher tunneling magnetoresistance and thus a higher read signal. Consequently, performance of the magnetic junction 100 may be improved. In addition, because the stack for the magnetic junction 100 is not as tall, the magnetic junction 100 may be easier to adequately define using ion milling. Fabrication may be improved.

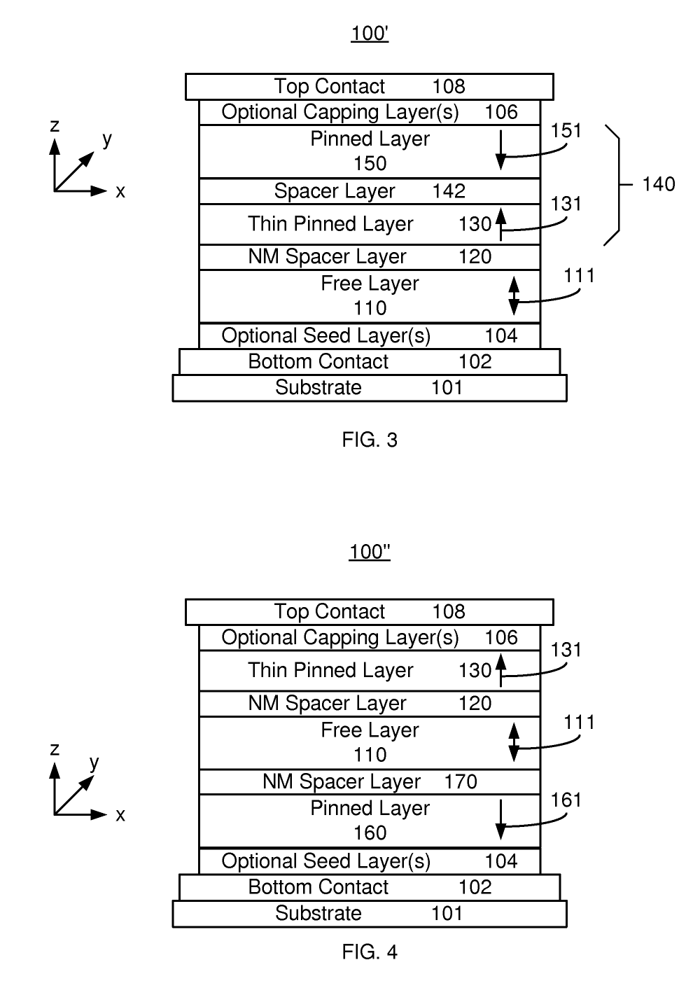

FIG. 3 depicts an exemplary embodiment of a magnetic junction 100′ including a thin pinned layer and usable in a magnetic memory programmable using spin transfer torque, as well as surrounding structures. For clarity, FIG. 3 is not to scale. The magnetic junction 100′ may be used in a magnetic device such as a STT-RAM and, therefore, in a variety of electronic devices. The magnetic junction 100′ is analogous to the magnetic junction 100. Consequently, similar components have analogous labels. The magnetic junction 100′ includes a free layer 110 having magnetic moment 111, a nonmagnetic spacer layer 120, and a pinned layer 130 having magnetic moment 131 that are analogous to the free layer 110 having magnetic moment 111, the nonmagnetic spacer layer 120, and the pinned layer 130 having magnetic moment 131, respectively, depicted in the magnetic junction 100. Also shown are an underlying substrate 101, bottom contact 102, top contact 108, optional seed layer(s) 104 and optional capping layer(s) 106 that may be analogous to the substrate 101, bottom contact 102, top contact 108, optional seed layer(s) 104 and optional capping layer(s) 106 for the magnetic junction 100. Although not shown, in another embodiment, the magnetic junction may include an additional pinned layer and an additional nonmagnetic spacer layer between the free layer 110 and the substrate 101. Thus, the magnetic junction 100′ might be a dual magnetic junction.

As can be seen in FIG. 3, the pinned layer 130 is part of a top pinned structure 140. The top pinned structure 140 includes the thin pinned layer 130, a spacer layer 142 that may be Ru or RuRh, and a second pinned layer 150. The second pinned layer 150 has a perpendicular magnetic anisotropy that exceeds its out-of-plane demagnetization energy. Thus, the magnetic moment 151 may be perpendicular to plane. In the embodiment shown, the pinned structure 140 is a SAF. Thus, the magnetic moments 131 and 151 of the layers 130 and 150, respectively, are aligned antiparallel. In some embodiments, the layers 130 and 150 are antiferromagnetically coupled through the spacer layer 142.

The pinned layers 130 and 150 may be multilayers. For example, the pinned layer 130 may include a CoFeB layer and at least one CoFe layer, as discussed above. Further, nonmagnetic insertion layers may be included between the Co layers. For example, a layer of Pt, Pd, Ru and/or another analogous material might be used between Co layers to enhance perpendicular magnetic anisotropy of the pinned layers 130. Similarly, the pinned layer 150 may be a multilayer. In some embodiments, the pinned layer 150 may include a Co layer and a [Pt/Co]ₙ multilayer, where n is an integer indicating the number of repeats of the Pt/Co bilayer. The pinned layer magnetic moment 151 may be used to balance the magnetic moment 131 at the free layer 110.

The magnetic junction 100′ may have improved performance. The free layer 110 and pinned layers 130 and 150 may have their magnetic moments oriented perpendicular-to-plane. The pinned layer 130 may be relatively thin and have a small Mst. The pinned layer 150 may be used offset the magnetic field from the pinned layer 130 at the free layer 110. Thus, the shift field at the free layer 110 may be further reduced. In some embodiments, the shift field at the free layer 110 may be brought to zero. The response of the free layer 110 may be more symmetric. The nonmagnetic spacer layer 120 may have the desired crystal structure for higher tunneling magnetoresistance and thus a higher read signal. Consequently, performance of the magnetic junction 100 may be improved. Because the Mst is smaller for the pinned layer 130, the Mst for the pinned layer 150 may also be smaller while still reducing the shift field at the free layer 110. The pinned layer 150 may, therefore, be made thinner. In some embodiments, the thickness of the pinned layer 150 may be less than two hundred Angstroms. In some embodiments, the pinned layer 150 may be approximately one hundred fifty Angstroms thick or less. The thickness of the stack for the magnetic junction 100′ may, therefore, be reduced over that of a conventional magnetic junction having a top SAF pinned structure. Because the stack height is reduced for the magnetic junction 100′, fabrication may be improved.

FIG. 4 depicts an exemplary embodiment of a magnetic junction 100″ including a thin pinned layer and usable in a magnetic memory programmable using spin transfer torque, as well as surrounding structures. For clarity, FIG. 4 is not to scale. The magnetic junction 100″ may be used in a magnetic device such as a STT-RAM and, therefore, in a variety of electronic devices. The magnetic junction 100″ is analogous to the magnetic junction(s) 100 and/or 100′. Consequently, similar components have analogous labels. The magnetic junction 100″ includes a free layer 110 having magnetic moment 111, a nonmagnetic spacer layer 120, and a pinned layer 130 having magnetic moment 131 that are analogous to the free layer 110 having magnetic moment 111, the nonmagnetic spacer layer 120, and the pinned layer 130 having magnetic moment 131, respectively, depicted in the magnetic junction 100. Also shown are an underlying substrate 101, bottom contact 102, top contact 108, optional seed layer(s) 104 and optional capping layer(s) 106 that may be analogous to the substrate 101, bottom contact 102, top contact 108, optional seed layer(s) 104 and optional capping layer(s) 106 for the magnetic junction 100.

As can be seen in FIG. 4, the magnetic junction 100″ also includes an additional (bottom) pinned layer 160 and an additional nonmagnetic (bottom) spacer layer 170. The nonmagnetic spacer layer 170 is analogous to the nonmagnetic spacer layer 120. Thus, the nonmagnetic spacer layer 170 may be conductive, a tunneling barrier layer, or have another structure. If it is a tunneling barrier layer, the nonmagnetic spacer layer 170 may be desired to be crystalline MgO having a 100 orientation. The pinned layer 160 has a magnetic moment 161 that is substantially fixed in place. Thus, the magnetic junction 100″ is a dual magnetic junction.

The perpendicular magnetic anisotropy of the pinned layer 160 exceeds its out-of-plane demagnetization energy. Thus, the magnetic moment 161 may be perpendicular to plane as shown in FIG. 4. The pinned layer 160 may be a single layer or a multilayer. In some embodiments, the pinned layer 160 may be a SAF or other analogous pinning structure. Other multilayers are also possible. In the embodiment shown, the pinned layers 130 and 160 are in a dual state, having magnetic moments 131 and 161, respectively, in opposite directions. In other embodiments, another state including but not limited to the antidual state (both moments 131 and 161 aligned) may be possible.

The magnetic junction 100″ may have improved performance. The layers 110, 130 and 160 may have their magnetic moments oriented perpendicular-to-plane. The pinned layer 130 may be relatively thin and, therefore, have a small Mst. The pinned layer 160 may be used offset the (smaller) magnetic field from the pinned layer 130 at the free layer 110. Thus, the shift field at the free layer 110 may be further reduced. The response of the free layer 110 may be more symmetric. The nonmagnetic spacer layers 120 and 170 may have the desired crystal structure for higher tunneling magnetoresistance and thus a higher read signal. Performance of the magnetic junction 100″ may be improved. The thickness of the stack for the magnetic junction 100″ may be reduced over that of a conventional magnetic junction. Because the stack height is reduced for the magnetic junction 100″, fabrication may be improved.

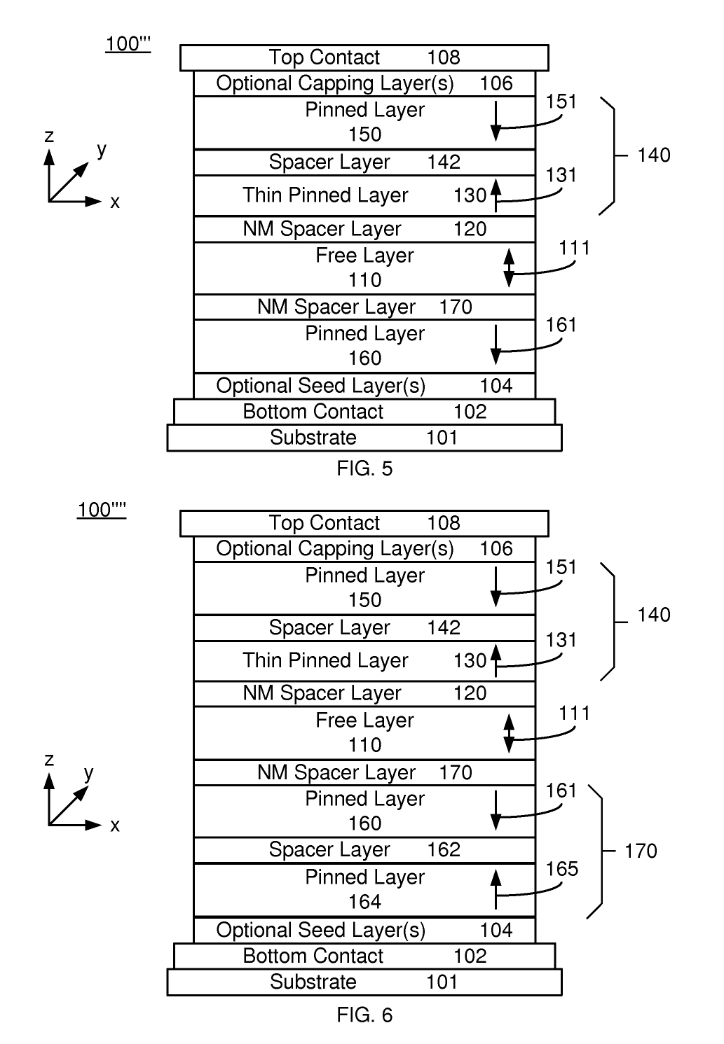

FIG. 5 depicts an exemplary embodiment of a magnetic junction 100″′ including a thin pinned layer and usable in a magnetic memory programmable using spin transfer torque, as well as surrounding structures. For clarity, FIG. 5 is not to scale. The magnetic junction 100″′ may be used in a magnetic device such as a STT-RAM and, therefore, in a variety of electronic devices. The magnetic junction 100″′ is analogous to the magnetic junction(s) 100, 100′ and/or 100″. Consequently, similar components have analogous labels. The magnetic junction 100″ includes a free layer 110 having magnetic moment 111, a nonmagnetic spacer layer 120, and a pinned layer 130 having magnetic moment 131 that are analogous to the free layer 110 having magnetic moment 111, the nonmagnetic spacer layer 120, and the pinned layer 130 having magnetic moment 131, respectively, depicted in the magnetic junction 100. Also shown are an underlying substrate 101, bottom contact 102, top contact 108, optional seed layer(s) 104 and optional capping layer(s) 106 that may be analogous to the substrate 101, bottom contact 102, top contact 108, optional seed layer(s) 104 and optional capping layer(s) 106 for the magnetic junction 100. The magnetic junction 100″′ also includes a pinned structure 140 of which the pinned layer 130 is a part. The pinned structure 140 is analogous to the pinned structure 140 depicted in FIG. 3. In addition, the magnetic junction 100″′ incorporates the pinned layer 160 analogous to the pinned layer 160 depicted in FIG. 4. Thus, the magnetic junction 100′″ is a dual magnetic junction.

The magnetic junction 100″′ may have improved performance. The magnetic layers 110, 130, 150 and 160 may have their magnetic moments oriented perpendicular-to-plane. The pinned layer 130 may be relatively thin and have a small Mst. The shift field at the free layer 110 due to the pinned layer 130 may be more easily compensated for using thinner layers 150 and/or 160. The response of the free layer 110 may be more symmetric. The nonmagnetic spacer layers 120 and 170 may have the desired crystal structure for high tunneling magnetoresistance. Consequently, performance of the magnetic junction 100 may be improved. The stack height for the magnetic junction 100″′ may also be reduced, allowing for improved fabrication.

FIG. 6 depicts an exemplary embodiment of a magnetic junction 100″″ including a thin pinned layer and usable in a magnetic memory programmable using spin transfer torque, as well as surrounding structures. For clarity, FIG. 6 is not to scale. The magnetic junction 100″″ may be used in a magnetic device such as a STT-RAM and, therefore, in a variety of electronic devices. The magnetic junction 100″″ is analogous to the magnetic junction(s) 100, 100′, 100″ and/or 100″. Consequently, similar components have analogous labels. The magnetic junction 100″ includes a free layer 110 having magnetic moment 111, a nonmagnetic spacer layer 120, and a pinned layer 130 having magnetic moment 131 that are analogous to the free layer 110 having magnetic moment 111, the nonmagnetic spacer layer 120, and the pinned layer 130 having magnetic moment 131, respectively, depicted in the magnetic junction 100. Also shown are an underlying substrate 101, bottom contact 102, top contact 108, optional seed layer(s) 104 and optional capping layer(s) 106 that may be analogous to the substrate 101, bottom contact 102, top contact 108, optional seed layer(s) 104 and optional capping layer(s) 106 for the magnetic junction 100.

The magnetic junction 100″″ also includes a pinned structure 140 of which the pinned layer 130 is a part. The pinned structure 140 is analogous to the pinned structure 140 depicted in FIG. 3. In addition, the magnetic junction 100″′ incorporates the pinned layer 160 analogous to the pinned layer 160 depicted in FIG. 4. Thus, the magnetic junction 100″′ is a dual magnetic junction. The pinned layer 160 is part of an additional pinned structure 170 that includes the pinned layer 160, a spacer layer 162 and an additional pinned layer 164. The layers 162 and 164 are analogous to the layers 142 and 150. Thus, the shift field from the pinned layer 160 may be offset by the field from the pinned layer 164.

The magnetic junction 100″′ may share the benefits of the magnetic junction(s) 100, 100′, 100″ and/or 100″′. The free layer 110 may be subjected to a smaller shift field, which may improve performance. The nonmagnetic spacer layers 120 and 170 may have the desired crystal structure for high tunneling magnetoresistance. The height of the magnetic junction 100″″ may also be less than a magnetic junction including thicker layers in lieu of the layer(s) 130 and/or 150. Because the stack height may be reduced for the magnetic junction 100″″, fabrication may be improved.

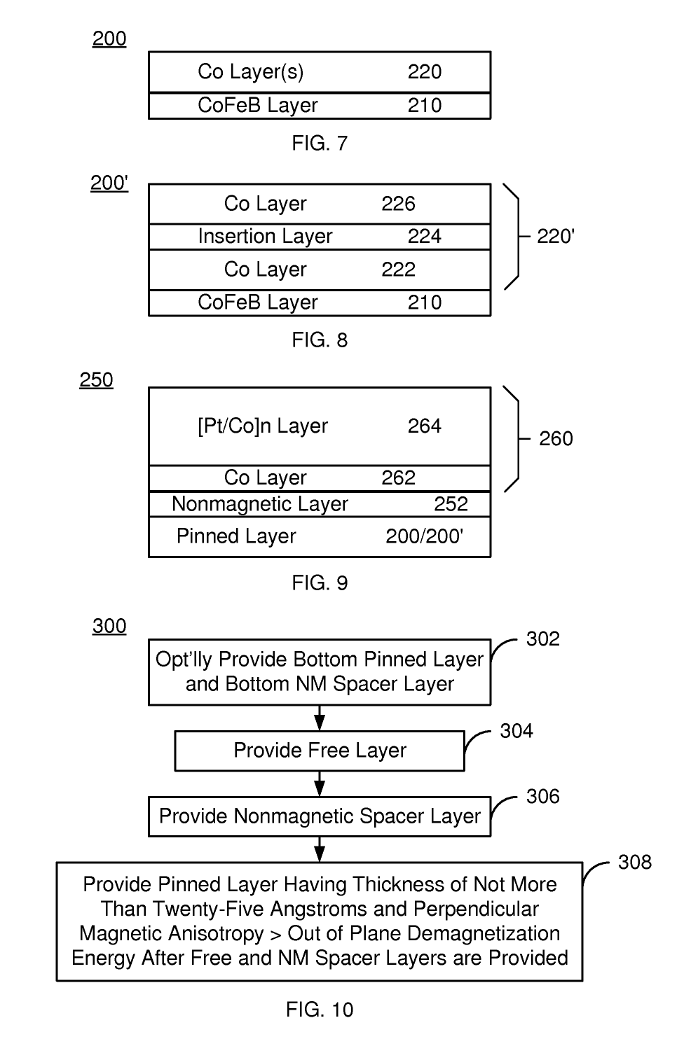

As discussed above, the thin pinned layer 130 may take various forms. FIG. 7 depicts an exemplary embodiment of a pinned layer 200 that may be used for the pinned layer 130. For clarity, FIG. 7 is not to scale. In the embodiment shown, the pinned layer 200 includes a CoFeB layer 210 and one or more Co layers 220. The pinned layer 200 is still thin and, therefore, has a thickness of not more than thirty Angstroms in the completed magnetic junction. In some embodiments, the thickness of the pinned layer 200 does not exceed twenty-five Angstroms. In addition, the perpendicular magnetic anisotropy energy of the pinned layer 200 is greater than its out-of-plane demagnetization energy. As a result, the magnetic moment (not shown) of the pinned layer may be perpendicular-to-plane. In such embodiments, a pinning layer is generally not used.

The CoFeB layer 210 is shown as below the Co layer(s) 220 because the CoFeB layer 210 is closer to the free layer of the magnetic junction in which the pinned layer 210 would be used. Thus, the pinned layer 200 would be used as a top pinned layer and is fabricated after the free layer. The thickness of the CoFeB layer 210 may be at least five Angstroms and not more than twenty Angstroms in the completed magnetic junction. The CoFeB layer 210 may, for example, be not more than fifteen Angstroms thick. In some embodiments, the CoFeB layer 210 is at least eight Angstroms and not more than twelve Angstroms thick after completion. In some embodiments, the CoFeB layer 210 includes a least one and not more than thirty atomic percent Co, at least forty and not more than ninety nine atomic percent Fe and at least one and not more than fifty atomic percent B. In some such embodiments, the CoFeB layer 210 stoichiometry may be as follows: Co 10-20 atomic percent, Fe: 60-90 atomic percent and B 10-30 atomic percent. The Co layer(s) 220 may have a thickness of at least three Angstroms and not more than five Angstroms.

A magnetic junction incorporating the pinned layer 200 as a top pinned layer (e.g. alone or as part of a top pinning structure) may have improved performance. The pinned layer 200 may be relatively thin. As a result, the pinned layer 200 has a small Mst. This allows the shift field due to the pinned layer 200 to be more readily compensated for. In addition, the stack height for the magnetic junction utilizing the pinned layer 200 may be reduced. Thus, performance and fabrication may be improved.

FIG. 8 depicts an exemplary embodiment of a pinned layer 200′ that may be used for the pinned layer 130 and is analogous to the pinned layer 200. For clarity, FIG. 8 is not to scale. In the embodiment shown, the pinned layer 200′ includes a CoFeB layer 210 and Co structure 220′. The pinned layer 200′ is still thin and, therefore, has a thickness of not more than thirty Angstroms in the completed magnetic junction. In some embodiments, the pinned layer 200′ is not more than twenty-five Angstroms thick. In addition, the perpendicular magnetic anisotropy energy of the pinned layer 200′ is greater than its out-of-plane demagnetization energy. As a result, the magnetic moment (not shown) of the pinned layer may be perpendicular-to-plane. In such embodiments, a pinning layer is generally not used.

The CoFeB layer 210 is analogous to the CoFeB layer 210 depicted in FIG. 7. The Co structure 220′ includes two Co layers 222 and 226 interleaved with and sandwiching an insertion layer 224. The insertion layer 224 may be used to enhance the perpendicular magnetic anisotropy of the Co layers 222 and 226. For example, the insertion layer may include one or more of Pt, Pd and/or Rh. In such embodiments, the Co layers are each at least three and not more than five Angstroms thick. The insertion layer may be at least two and not more than five Angstroms thick in such embodiments. However, the thickness of the pinned layer 200′ including the CoFeB layer, Co layers and insertion layer may still be desired not to exceed thirty Angstroms, and in some embodiments does not exceed twenty-five Angstroms.

A magnetic junction incorporating the pinned layer 200′ as a top pinned layer (e.g. alone or as part of a top pinning structure) may have improved performance. The pinned layer 200′ may be relatively thin. As a result, the pinned layer 200′ has a small Mst. This allows the shift field due to the pinned layer 200′ to be more readily compensated for. In addition, the stack height for the magnetic junction utilizing the pinned layer 200′ may be reduced. Thus, performance and fabrication may be improved.

FIG. 9 depicts an exemplary embodiment of a pinned pinning structure 250 that may in corporate a pinned layer such as the pinned layer 130, 200 and/or 210. The pinning structure 250 may thus be analogous to the pinning structure 140 depicted in FIGS. 3, 5 and 6. For clarity, FIG. 9 is not to scale.

The pinning structure 250 includes a pinned layer 200/200′ that is depicted in FIGS. 7 and 8. The pinning structure 250 also includes a nonmagnetic layer 252 and a pinned layer 260. The nonmagnetic layer 252 and pinned layer 260 are analogous to the layers 142 and 150, respectively. In the embodiment shown, the pinned layer 260 includes a Co layer 262 and a multilayer 264 including number (n) of repeats of a Pt/Co bilayer. In some embodiments, the Pt layer of the Pt/Co bilayer would adjoin the Co layer 222. The pinned layer 260 may be used to offset the shift field of the pinned layer 200/200′ at the free layer.

A magnetic junction incorporating the pinned structure 250 as a top pinned layer may have improved performance. The pinned layer 200/200′ may be relatively thin, allowing the pinned layer 260 to be made thinner. The pinned layer 260 may be less than two hundred Angstroms thick. In some embodiments, the pinned layer 260 may have a thickness of one hundred fifty Angstroms or below. This allows the shift field due to the pinned layer 200′ to be more readily compensated for and the stack height to be reduced. Thus, performance and fabrication may be improved.

FIG. 10 depicts an exemplary embodiment of a method 300 for fabricating a magnetic junction including a thin pinned layer and usable in a magnetic device such as a STT-RAM and, therefore, in a variety of electronic devices. For simplicity, some steps may be omitted, performed in another or combined. Further, the method 300 may start after other steps in forming a magnetic memory have been performed. For simplicity, the method 300 is described in the context of the magnetic junctions 100 and 100″. However, other magnetic junctions may be formed.

A bottom pinned layer and a nonmagnetic spacer layer may optionally be provided, via step 302. Step 302 includes multiple substeps. For example, the bottom pinned layer is deposited first, followed by the nonmagnetic spacer layer. In some embodiments, the layers 160/160′ and 170 are provided in step 302. The edges of the magnetic junction, including those of the pinned layer 160 and nonmagnetic spacer layer 170, may be defined immediately after deposition or at a later time. For example, once the remaining layers of the magnetic junction have been deposited, the magnetic junction may be defined. In some embodiments, an ion mill may be performed. Thus, portions of step 302 may be spread out over time. Step 302 may be performed if the magnetic junction(s) 100″, 100″′ and/or 100″″ are being fabricated. If the magnetic junctions 100 and/or 100′ are fabricated, then step 302 may be omitted.

A free layer 110 that may have a perpendicular-to-plane magnetic moment is provided on the substrate, via step 304. In some embodiments, step 304 includes depositing the material(s) for the free layer 110. The free layer may be deposited on seed layers or other layers, such as the nonmagnetic spacer layer 170. The edges of the magnetic junction, including those of the free layer 110, may be defined immediately after deposition or at a later time. For example, once the remaining layers of the magnetic junction have been deposited, the magnetic junction may be defined. In some embodiments, an ion mill may be performed. Thus, portions of step 304 may be spread out over time.

A nonmagnetic spacer layer 120 is provided, via step 306. Step 306 may include depositing MgO, which forms a tunneling barrier layer. In some embodiments, step 304 may include depositing MgO using, for example, radio frequency (RF) sputtering. In other embodiments, metallic Mg may be deposited, then oxidized in step 306. As discussed above with respect to steps 302 and 304, the edges of the nonmagnetic spacer layer may be defined at a later time, for example after deposition of the remaining layers of the magnetic junction. Further, it is noted that the MgO nonmagnetic spacer layer 120 may be amorphous as-deposited in step 306.

A thin pinned layer 130 is provided, via step 308. Step 308 is performed such that the pinned layer 130 may remain thin, yet have a perpendicular magnetic anisotropy energy that exceeds the out-of-plane demagnetization energy. In some embodiments, step 308 includes depositing a magnetic layer, such as CoFeB. The magnetic layer is thicker as-deposited than is desired in the final device. A sacrificial nonmagnetic layer is deposited on the magnetic layer and the portion of the magnetic junction annealed. An anneal performed in step 308 may also aid in crystallizing the nonmagnetic spacer layer 120 to have the desired crystal structure. The sacrificial layer is then removed. As part of this removal, a portion of the underlying magnetic layer may also be removed. One or more additional magnetic layers (and insertion layer(s)) may also be deposited as part of step 308. In other embodiments, other methods for providing a pinned layer such as the pinned layer 130 may be used. The edges of the magnetic junction, including those of the pinned layer 130, may be defined immediately after deposition or at a later time. Fabrication of the magnetic junction may then be completed. If a pinning structure such as the structure 140 is to be fabricated, then a spacer layer through which antiferromagnetic coupling may be achieved, such as the layer 142 and an additional pinned layer such as the layer 150 may also be fabricated.

Using the method 300, the magnetic junction 100, 100′, 100″ and/or 100″′ may be formed. Thus, the benefits of the magnetic junction(s) 100, 100′, 100″ and/or 100″′ may be achieved. In particular, a thin pinned layer 130 having a perpendicular magnetic anisotropy energy that exceeds the out-of-plane demagnetization energy may be achieved while ensuring that the nonmagnetic spacer layer has the desired crystal structure.

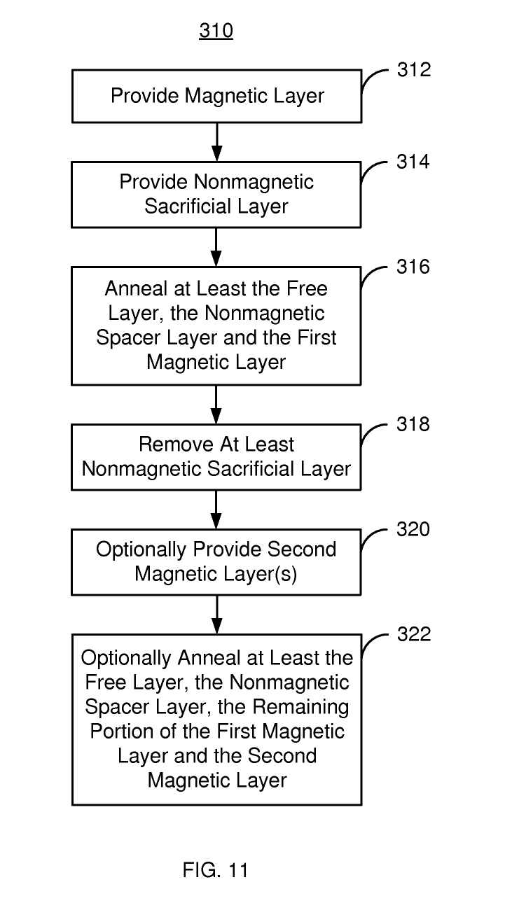

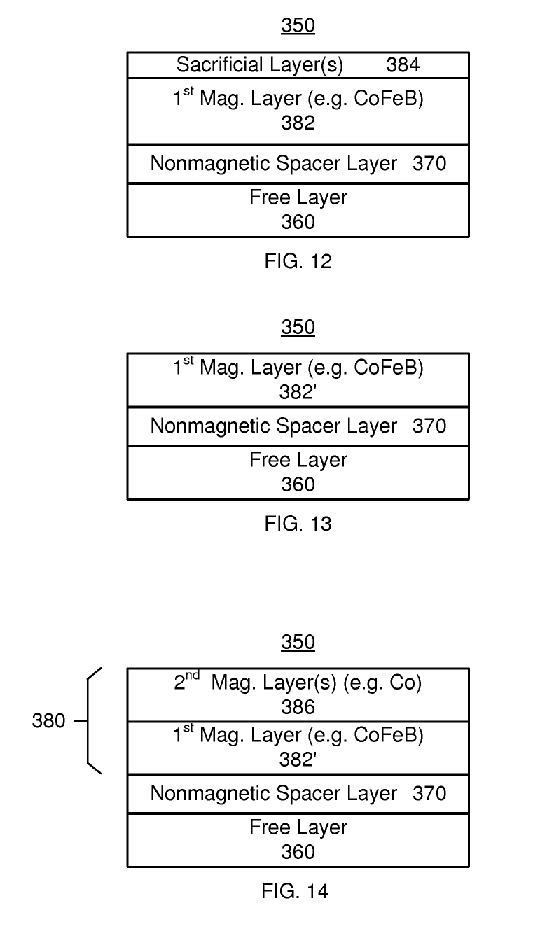

FIG. 11 depicts an exemplary embodiment of a method 310 for fabricating a thin pinned layer in magnetic junction including a thin pinned layer and usable in a magnetic device such as a STT-RAM and, therefore, in a variety of electronic devices. For simplicity, some steps may be omitted, performed in another or combined. Further, the method 310 may start after other steps in forming a magnetic memory have been performed. FIGS. 12-15 depict an exemplary embodiment of a magnetic junction 350 that may be fabricated using the method 310. FIGS. 12-15 depict the magnetic junction 350 during fabrication and are not to scale. Referring to FIGS. 11-15, only a portion of the final magnetic junction 350 is shown in some drawings. The method 310 is described in the context of the magnetic junction 350. However, other magnetic junctions may be formed. The method 310 commences after the free layer and nonmagnetic spacer layer have been deposited. In some embodiments, the nonmagnetic spacer layer may be MgO. The MgO layer may be amorphous at the start of the method 310. Thus, an anneal which crystallizes the MgO layer may not be formed. If a dual magnetic junction is being fabricated, then the method 310 starts after not only fabrication of the free layer and spacer layer adjoining the pinned layer being formed, but also after an additional pinned layer and an additional nonmagnetic spacer layer have been provided between the substrate and the free layer.

A first magnetic layer is deposited, via step 312. Step 312 may include depositing a CoFeB layer. The stoichiometry of the CoFeB layer may be in the ranges described above. The CoFeB layer deposited in step 312 may be thicker than in the finished device. In some embodiments, the CoFeB layer may have a thickness of at least twenty Angstroms and not more than thirty Angstroms. In some embodiments, the CoFeB layer may be not more than twenty-five Angstroms thick. In some embodiments, the first magnetic layer is deposited in step 320. The edges of the layer are defined after the remaining layers of the magnetic junction have been deposited. For example, after deposition of the entire stack, the stack may be masked and exposed portions of the stack removed via ion milling. In other embodiments, the edges of the layers may be individually defined. However, this may be suboptimal as misalignments between the edges of the layers may occur.

At least one nonmagnetic sacrificial layer is deposited on the first, CoFeB layer, via step 314. In some embodiments, the nonmagnetic sacrificial layer is W. The sacrificial layer is desired to improve the perpendicular magnetic anisotropy of the underlying magnetic layer. Thus, another nonmagnetic material that may be capable of preserving the perpendicular magnetic anisotropy may be used. The thickness of the sacrificial layer is small. Thus, the sacrificial layer may be less than ten Angstroms thick. In some embodiments, the sacrificial layer may be at least two and less than five Angstroms thick.

FIG. 12 depicts the magnetic junction 350 after step 314 is performed. Thus, the free layer 360 and nonmagnetic spacer layer 370 that are formed before the start of the method 310 are shown. In some embodiments, an additional nonmagnetic spacer layer (not shown) and pinned layer (not shown) are below the free layer 360. Thus, the magnetic junction 350 may be a single or a dual magnetic junction. The nonmagnetic spacer layer 370 may be an MgO tunneling barrier layer. In such cases, after step 314, the nonmagnetic spacer layer 370 may still be amorphous. Also shown are the first magnetic layer 382 and the sacrificial layer 384. In the embodiment shown, a single sacrificial layer is depicted. The magnetic layer 382 may include CoFeB and may be over twenty Angstroms thick, as indicated above. The sacrificial layer 384 has a thickness in the ranges discussed above.

The nonmagnetic spacer layer 370 may be amorphous as-deposited. However, the nonmagnetic spacer layer 370 is desired to be crystalline. For example, crystalline MgO with a (100) orientation may be desired for enhanced tunneling magnetoresistance of the magnetic junction 350. Consequently, the portion of the magnetic junction 350 that has already been formed is annealed at temperature(s) of at least three hundred fifty degrees Celsius. Thus, at least the free layer 360, the nonmagnetic spacer layer 370, the magnetic layer 382 and the sacrificial layer 384 are annealed, via step 316. In some embodiments, step 316 includes performing a rapid thermal anneal (RTA). In such an embodiments, the already-formed portion of the magnetic junction may be annealed for minutes or less. However, in other embodiments, the anneal may be performed in another manner, including but not limited to block heating. In some embodiments, the portion of the magnetic junction may be annealed in step 316 for at least 10 minutes and not more than ten hours. The anneal in step 316 may also be broken into multiple anneals. In such embodiments, the anneal times may differ. For example, a first anneal may be for less than ten minutes but at least one minute, while a second anneal may be at least ten minutes to hours long. Further, in some embodiments, higher anneal temperatures may be used. The anneal temperature may be desired not to exceed six hundred degrees Celsius. In some embodiments, the anneal is performed at a temperature of at least four hundred degrees Celsius. In some such embodiments, the anneal temperature is at least four hundred fifty degrees Celsius. The anneal temperature in some embodiments may be desired not to exceed five hundred degrees Celsius. In some cases, however, the desired temperature range for the anneal is from three hundred fifty degrees Celsius through four hundred fifty degrees Celsius.

The sacrificial layer 384 is removed, via step 318. In some embodiments, step 318 includes plasma etching the portion of the magnetic 350 that has been formed in order to remove the sacrificial layer 384. To ensure complete removal of the nonmagnetic material in the sacrificial layer, a portion of the underlying magnetic layer 382 is also removed. FIG. 13 depicts the magnetic junction 350 after step 318 is performed. Thus, the sacrificial layer 384 has been removed. The first magnetic layer 382′ has a thickness than the as-deposited layer 382. The final thickness of the first magnetic layer 382′ is in the range described above. For example, the first magnetic layer 382′ has a thickness of be at least five Angstroms and not more than twenty Angstroms. In some embodiments, the first magnetic layer 382′ is at least eight Angstroms and not more than twelve Angstroms thick.

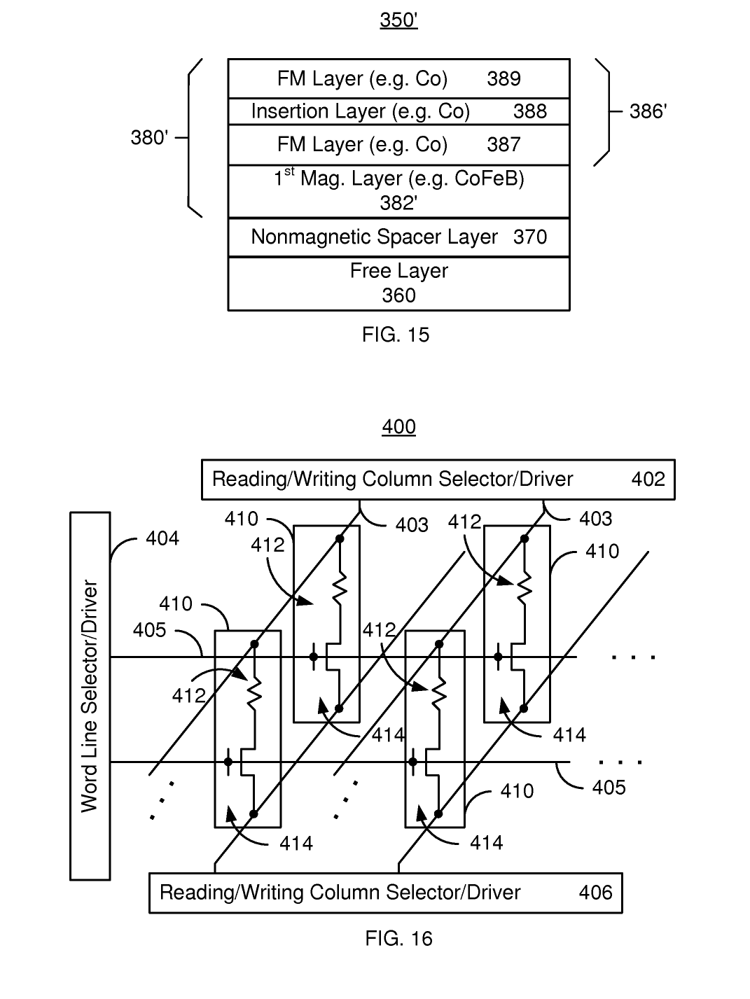

At least one additional magnetic layer may optionally be provided, via step 320. For example, step 320 may be used to provide one or more Co layers. In some embodiments, multiple Co layers may be interleaved with a nonmagnetic insertion layer. The Co layer(s) may have a thickness of at least three Angstroms and not more than five Angstroms. Other thicknesses are possible. FIG. 14 depicts one embodiment of the magnetic junction 350 in which step 320 is performed. Thus, a second magnetic layer 386 has been deposited. In the embodiment shown in FIG. 14, the second magnetic layer 386 is a single layer that may be Co. The pinned layer 380 thus includes the first magnetic layer 382′ and the second magnetic layer 386. FIG. 15 depicts another embodiment of the magnetic junction 350′ in which step 320 has been performed. In the magnetic junction 380′ the second magnetic layer 386′ includes three layers 387, 388 and 389. Layers 387 and 389 are magnetic layers, such as Co. Layer 388 is an insertion layer, such as Pt, Pd, Rh or the like. The pinned layer 380′ thus includes the magnetic layer 382′ and the composite layer 386′ including layers 387, 388 and 389. In both magnetic junctions 350 and 350′, the pinned layers 380 and 380′ have total thicknesses not exceeding thirty Angstroms. In some embodiments, the pinned layers 380 and 380′ each has a total thickness of not more than twenty-five Angstroms. In addition, the pinned layers 380 and 380′ have perpendicular magnetic anisotropies that exceed the out-of-plane demagnetization energy. Thus, the magnetic moments (not shown) of the layers 380 and 380′ may be oriented perpendicular-to-plane.

In some embodiments, step 320 may be omitted. In such embodiments, a nonmagnetic layer, such as the layer 142 may adjoin the magnetic layer 382′. Thus, a pinned structure such as the pinned structure 140 depicted in FIGS. 3 and 5 may be fabricated.

An additional thermal treatment may optionally be performed, via step 322. The layers 360, 370 and 382′/380/380′ that have already been deposited may be subjected to an additional heat treatment. In some embodiments, this anneal is at lower temperature(s) than the anneal performed in step 316. For example, the temperature(s) used in step 322 may not exceed three hundred fifty degrees Celsius and are at least two hundred degrees Celsius. In some such embodiments, the anneal is at temperatures of at least two hundred fifty degrees Celsius and not exceeding three hundred degrees Celsius. Alternatively, step 322 may be omitted.

Fabrication of the magnetic junction 350/350′ may be completed. For example, a nonmagnetic spacer layer and additional pinned layer such as the layers 142 and 150 may be deposited. The edges of the magnetic junction 350 may also be defined. The device in which the magnetic junction 350/350′ may also be finished.

Using the method 310, the magnetic junction(s) 350/350′, as well as the magnetic junction(s) 100, 100′, 100″ and/or 100″′ may be formed. Thus, the benefits of the magnetic junction(s) 100, 100′, 100″, 100″′, 350 and/or 350′ may be achieved. In particular, a thin pinned layer 130 having a perpendicular magnetic anisotropy energy that exceeds the out-of-plane demagnetization energy may be achieved while ensuring that the nonmagnetic spacer layer has the desired crystal structure. Further, any additional pinned layer such as the layer 150 may have a reduced thickness. The shift field at the free layer may also be reduced. Thus, performance and production of the magnetic junction(s) 100, 100′, 100″, 100″′, 100″″, 350 and/or 250′ may be improved.

FIG. 16 depicts an exemplary embodiment of a memory 400 that may use one or more of the magnetic junctions 100, 100′, 100″, 100″′, 100″″, 350 and/or 350′ including pinned layer(s) 130, 200, 200′, 380 and/or 380′. The magnetic memory 400 includes reading/writing column select drivers 402 and 406 as well as word line select driver 404. Note that other and/or different components may be provided. The storage region of the memory 400 includes magnetic storage cells 410. Each magnetic storage cell includes at least one magnetic junction 412 and at least one selection device 414. In some embodiments, the selection device 414 is a transistor. The magnetic junctions 412 may be one of the magnetic junctions 100, 100′, 100″, 100″′, 100″″, 350 and/or 350′ disclosed herein. Although one magnetic junction 412 is shown per cell 410, in other embodiments, another number of magnetic junctions 412 may be provided per cell. As such, the magnetic memory 400 may enjoy the benefits described above.

A method and system for providing a magnetic junction and a memory fabricated using the magnetic junction has been described. The method and system have been described in accordance with the exemplary embodiments shown, and one of ordinary skill in the art will readily recognize that there could be variations to the embodiments, and any variations would be within the spirit and scope of the method and system. Accordingly, many modifications may be made by one of ordinary skill in the art without departing from the spirit and scope of the appended claims.

We claim:

1. A magnetic junction residing on a substrate and usable in a magnetic device comprising:
a free layer, the free layer being switchable between a plurality of stable magnetic states when a write current is passed through the magnetic junction;
a nonmagnetic spacer layer; and
a pinned layer, the nonmagnetic spacer layer residing between the pinned layer and the free layer, the nonmagnetic spacer layer and the free layer being between the pinned layer and the substrate, the pinned layer having a pinned layer perpendicular magnetic anisotropy energy greater than a pinned layer out-of-plane demagnetization energy, the pinned layer having a thickness of not more than thirty Angstroms.

2. The magnetic junction of claim 1 wherein the pinned layer includes a CoFeB layer and at least one Co layer.

3. The magnetic junction of claim 2 wherein the CoFeB layer has a first thickness of at least ten Angstroms and not more than twenty Angstroms and wherein the at least one Co layer has a thickness of at least three Angstroms and not more than five Angstroms.

4. The magnetic junction of claim 2 wherein the at least one Co layer includes a first Co layer and a second Co layer, the pinned layer further including:
a nonmagnetic insertion layer between the first Co layer and the second Co layer.

5. The magnetic junction of claim 4 wherein the first Co layer has a first thickness of not more than five Angstroms, the second Co layer has a second thickness of not more than five Angstroms, the nonmagnetic insertion layer has a third thickness of not more than five Angstroms, the nonmagnetic insertion layer includes at least one of Pt, Pd and Rh, and wherein the CoFeB layer has a thickness of not more than twenty Angstroms.

6. The magnetic junction of claim 1 wherein the pinned layer is part of a top pinned structure, the top pinned structure also including:
a nonmagnetic layer, the pinned layer being between the free layer and the nonmagnetic layer; and
an additional pinned layer, the nonmagnetic layer being between the additional pinned layer and the pinned layer.

7. The magnetic junction of claim 1 further comprising:
a bottom nonmagnetic layer; and
a bottom pinned layer, the bottom nonmagnetic layer being between the free layer and the bottom pinned layer, the bottom pinned layer and the bottom nonmagnetic layer being between the free layer and the substrate.

8. The magnetic junction of claim 7 wherein the bottom pinned layer includes a plurality of magnetic layers and at least one nonmagnetic layer, the plurality of magnetic layers interleaved with and sandwiching the at least one nonmagnetic layer.

9. A magnetic memory residing on a substrate, the magnetic memory comprising:
a plurality of magnetic storage cells, each of the plurality of magnetic storage cells including at least one magnetic junction, the at least one magnetic junction including a free layer, a nonmagnetic spacer layer, and a pinned layer, the nonmagnetic spacer layer residing between the pinned layer and the free layer, the free layer being and the nonmagnetic spacer layer being between the pinned layer and the substrate, the pinned layer having a perpendicular magnetic anisotropy energy greater than an out-of-plane demagnetization energy, the free layer being switchable between a plurality of stable magnetic states when a write current is passed through the magnetic junction, the pinned layer having a thickness of not more than thirty Angstroms; and
a plurality of bit lines coupled with the plurality of magnetic storage cells.

10. The magnetic memory of claim 9 wherein the pinned layer includes a CoFeB layer and at least one Co layer, the CoFeB layer having a first thickness of at least ten Angstroms and not more than twenty Angstroms, the at least one Co layer having a thickness of at least three Angstroms and not more than five Angstroms.

11. The memory of claim 10 wherein the at least one Co layer includes a first Co layer and a second Co layer, the pinned layer further including:
a nonmagnetic insertion layer between the first Co layer and the second Co layer, the first Co layer having a first thickness of not more than five Angstroms, the second Co layer having a second thickness of not more than five Angstroms, the nonmagnetic insertion layer having a third thickness of not more than five Angstroms, the nonmagnetic insertion layer includes at least one of Pt, Pd and Rh, and wherein the CoFeB layer has a thickness of not more than twenty Angstroms.

12. The magnetic memory of claim 9 wherein the pinned layer is part of a top pinned structure, the top pinned structure also including:
a nonmagnetic layer, the pinned layer being between the free layer and the nonmagnetic layer; and
an additional pinned layer, the nonmagnetic layer being between the additional pinned layer and the pinned layer.

13. A method for providing magnetic junction residing on a substrate and usable in a magnetic device, the method comprising:
providing a free layer, the free layer being switchable between a plurality of stable magnetic states when a write current is passed through the magnetic junction;
providing a nonmagnetic spacer layer; and
providing a pinned layer, the nonmagnetic spacer layer residing between the pinned layer and the free layer, the nonmagnetic spacer layer and the free layer being between the pinned layer and the substrate, the pinned layer having a pinned layer perpendicular magnetic anisotropy energy greater than a pinned layer out-of-plane demagnetization energy, the pinned layer having a thickness of not more than thirty Angstroms, the step of providing the pinned layer further including:
providing a first magnetic layer;
providing a nonmagnetic sacrificial layer on the first magnetic layer;
annealing at least the free layer, the nonmagnetic spacer layer, the first magnetic layer and the nonmagnetic sacrificial layer;
removing the nonmagnetic sacrificial layer and a portion of the first magnetic layer after the annealing step; and
optionally providing at least a second magnetic layer on a remaining portion of the first magnetic layer after the removing step.

14. The method of claim 13 wherein the annealing step further includes:
annealing the at least the free layer, the nonmagnetic spacer layer, the first magnetic layer and the nonmagnetic sacrificial layer at an anneal temperature of at least three hundred fifty degrees Celsius

15. The method of claim 13 wherein the first magnetic layer is a CoFeB layer and the second magnetic layer includes at least one Co layer, the CoFeB layer having a first thickness of at least ten Angstroms and not more than twenty Angstroms, the at least one Co layer having a thickness of at least three Angstroms and not more than five Angstroms.

16. The method of claim 15 wherein the first magnetic layer has an as-deposited thickness of at least twenty Angstroms and not more than twenty-five Angstroms before the nonmagnetic sacrificial layer is deposited, the CoFeB layer having the first thickness after the step or removing the nonmagnetic sacrificial layer.

17. The method of claim 15 wherein the at least one Co layer includes a first Co layer and a second Co layer, the step of providing the pinned layer further including:
providing a nonmagnetic insertion layer between the first Co layer and the second Co layer, the first Co layer having a first thickness of not more than five Angstroms, the second Co layer having a second thickness of not more than five Angstroms, the nonmagnetic insertion layer having a third thickness of not more than five Angstroms, the nonmagnetic insertion layer includes at least one of Pt, Pd and Rh, and wherein the CoFeB layer has a thickness of not more than twenty Angstroms.

18. The method of claim 15 further comprising:
performing an additional anneal after the step of providing the second magnetic layer, the additional anneal having a temperature of at least two hundred fifty degrees Celsius and not more than three hundred fifty degrees Celsius.

19. The method of claim 13 further comprising:
providing a nonmagnetic layer on the pinned layer; and
providing an additional pinned layer, the nonmagnetic layer being between the additional pinned layer and the pinned layer.

20. The method of claim 13 further comprising:
providing a bottom nonmagnetic layer; and
providing a bottom pinned layer, the bottom nonmagnetic layer being between the free layer and the bottom pinned layer, the bottom pinned layer and the bottom nonmagnetic layer being between the free layer and the substrate.
